(19) United States
(12) Patent Application Publication
(10) Pub. No.: US 2025/0255111 A1
(43) Pub. Date: Aug. 7, 2025

(54) DISPLAY PANEL AND ELECTRONIC APPARATUS

(71) Applicant: Samsung Display Co., Ltd., Yongin-Si (KR)

(72) Inventors: Seongyong Hwang, Yongin-si (KR); Chanyoung Kim, Yongin-si (KR); Beohmrock Choi, Yongin-si (KR); Sangwoo Kang, Yongin-si (KR); Choongyoul Im, Yongin-si (KR); Seongmin Cho, Yongin-si (KR)

(21) Appl. No.: 19/030,074

(22) Filed: Jan. 17, 2025

(30) Foreign Application Priority Data
Feb. 7, 2024 (KR) 10-2024-0019175

(51) Int. Cl. H10K 59/122; H10K 59/38; H10K 59/80; H10K 59/95

(52) U.S. Cl. CPC H10K 59/122; H10K 59/38; H10K 59/8792; H10K 59/95

(57) ABSTRACT

A display panel includes a substrate including a first display area and a second display area that is at least partially surrounded by the first display area, the first display area and the second display area having a plurality of emission areas, and the second display area having a transmission area that is positioned between neighboring emission areas of the plurality of emission areas, a bank layer disposed on the substrate and having a first bank opening portion corresponding to the transmission area, and a light-blocking layer disposed on the bank layer and having a transmission opening portion defined by a sidewall, the transmission opening portion corresponding to the transmission area and having a greater area than an area of the first bank opening portion, wherein at least a portion of the sidewall defining the transmission opening portion is curved.

### CROSS-REFERENCE TO RELATED APPLICATION

This application is based on and claims priority, under 35 U.S.C. § 119, to Korean Patent Application No. 10-2024-0019175 filed on Feb. 7, 2024 in the Korean Intellectual Property Office, the disclosure of which is incorporated by reference herein in its entirety.

### BACKGROUND

### 1. Field

One or more embodiments relate to a display panel and an electronic apparatus including the display panel.

### 2. Description of the Related Art

Recently, display panels have become more diversified in their uses. In addition, as display panels have become thinner and lighter, the range of use of display panels has widened.

The variety of functions connected or linked to a display panel has increased at the same time that the proportion of an area occupied by a display area has also increased on the display panel. To increase the variety of functions while accommodating the enlarging display area, research continues on display panels having areas positioned inside the display area to perform various functions other than displaying an image.

### SUMMARY

A component, such as a camera or a sensor, may be arranged in a display device to add various functions. To arrange a component while securing a larger display area, the component may be arranged to overlap the display area. As a method of arranging a component, a display panel may include a transmission area through which wavelengths, such as light or sound, may pass. One or more embodiments include a display panel having the above structure and an electronic apparatus including the display panel.

Additional aspects will be set forth in part in the description which follows and, in part, will be apparent from the description, or may be learned by practice of the presented embodiments of the disclosure.

According to one or more embodiments, a display panel includes a substrate including a first display area and a second display area that is at least partially surrounded by the first display area, the first display area and the second display area having a plurality of emission areas, and the second display area having a transmission area that is positioned between neighboring emission areas of the plurality of emission areas, a bank layer disposed on the substrate and having a first bank opening portion corresponding to the transmission area, and a light-blocking layer disposed on the bank layer and having a transmission opening portion defined by a sidewall, the transmission opening portion corresponding to the transmission area and having a greater area than an area of the first bank opening portion, wherein at least a portion of the sidewall defining transmission opening portion is curved.

According to an embodiment, the transmission opening portion may have a circular shape.

According to an embodiment, the transmission opening portion may have an oval shape.

According to an embodiment, the transmission opening portion may include a first portion having a shape of at least a portion of a circle or an oval, and a second portion having a shape of at least a portion of a circle or an oval.

According to an embodiment, the transmission opening portion may include a plurality of fourth portions respectively arranged at vertices of an imaginary rectangle and each having a shape of at least a portion of a circle or an oval, and a third portion providing a wall connecting neighboring ones of the fourth portions.

According to an embodiment, the transmission opening portion may include a plurality of sixth portions each having a shape of at least a portion of a circle or an oval, and a fifth portion having a straight edge and arranged between the sixth portions.

According to an embodiment, the transmission opening portion may be defined by a sidewall of the light-blocking layer.

According to an embodiment, an edge defining the first bank opening portion may surround the transmission opening portion.

According to an embodiment, the first bank opening portion may have a polygonal shape.

According to an embodiment, the first bank opening portion may have a rectangular shape.

According to an embodiment, the display panel may further include a pixel circuit layer disposed on the substrate and including a pixel circuit.

According to an embodiment, the display panel may further include a light-emitting element including a first electrode disposed on the pixel circuit layer, an emission layer on the first electrode, and a second electrode on the emission layer.

According to an embodiment, the bank layer may further include a second bank opening portion having a sidewall on the first electrode.

According to an embodiment, the light-blocking layer may further include first, second, and third openings respectively overlapping the plurality of emission areas, and color filters are respectively arranged in the first, second, and third openings of the light-blocking layer.

According to one or more embodiments, an electronic apparatus includes a display panel including a first display area and a second display area that is at least partially surrounded by the first display area, and a component disposed below the display panel and positioned in the second display area, wherein the display panel further includes a substrate including a plurality of emission areas and a transmission area, the plurality of emission areas being arranged in the first display area and the second display area, and the transmission area being arranged in the second display area and positioned between neighboring emission areas of the plurality of emission areas, a bank layer disposed on the substrate and having a first bank opening portion corresponding to the transmission area, and a light-blocking layer disposed on the bank layer and having a sidewall defining transmission opening portion, the transmission opening portion corresponding to the transmission area and having a greater area than an area of the first bank opening portion, wherein at least a portion of the sidewall defining the transmission opening portion is curved.

According to an embodiment, the transmission opening portion may be defined by a side wall of the light-blocking layer.

According to an embodiment, the first bank opening portion may be arranged to surround the transmission opening portion.

According to an embodiment, the first bank opening portion may have a polygonal shape.

According to an embodiment, the component may include a sensor using light.

According to an embodiment, the electronic apparatus may further include a pixel circuit layer disposed on the substrate and including a pixel circuit, and a light-emitting element including a first electrode disposed on the pixel circuit layer, an emission layer on the first electrode, and a second electrode on the emission layer, wherein the bank layer may further include a second bank opening portion having an edge on the first electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view of an electronic apparatus according to an embodiment;

FIGS. 2 and 3 are schematic perspective views of a foldable electronic apparatus according to an embodiment;

FIG. 4 is a schematic plan view of an electronic apparatus according to another embodiment;

FIGS. 5A and 5B are cross-sectional views each illustrating a portion of an electronic apparatus according to an embodiment;

FIG. 6 is a plan view of an input sensing layer of a display apparatus according to an embodiment;

FIG. 7 is a cross-sectional view of the input sensing layer of FIG. 6, taken along a line VII-VII′ in FIG. 6;

FIG. 8A is an enlarged plan view of VIIIa of FIG. 6; FIG. 8B is an enlarged plan view of VIIIb of FIG. 6;

FIG. 9 is a plan view illustrating a first display area of a display panel according to an embodiment;

FIG. 10 is a plan view illustrating a second display area of a display panel according to an embodiment;

FIGS. 11 to 14 are plan views each showing a first transmission opening portion of a light-blocking layer and a bank opening portion of a bank layer, according to embodiments;

FIG. 15 is a cross-sectional view of a display panel according to an embodiment, taken along a line XI-XI′ of FIGS. 9 and 10; and

FIG. 16 is a cross-sectional view of a display panel according to an embodiment, taken along a line XII-XII′ of FIG. 10.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described below by referring to the figures, to explain aspects of the present description. As used herein, the term “and/or” includes any and all combinations of one or more of the associated listed items. Throughout the disclosure, the expression “at least one of a, b or c” encompasses the possibilities of only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the disclosure, “A and/or B” may include “A,” “B,” or “A and B.” In addition, “at least one of A and B” or “at least one selected from A and B” may include “A,” “B,” or “A and B.”

It will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

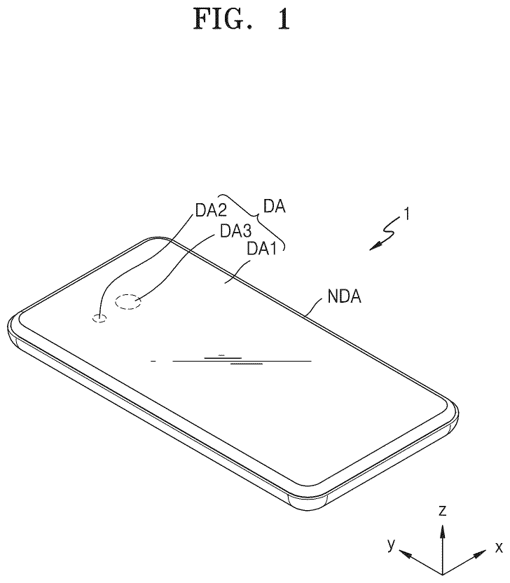

FIG. 1 is a perspective view of an electronic apparatus according to an embodiment.

An electronic apparatus 1 according to an embodiment is an apparatus that displays a video or a still image, which may be a portable electronic apparatus, such as a mobile phone, a smart phone, a tablet personal computer (PC), a mobile communication terminal, an electronic notebook, an electronic book, a portable multimedia player (PMP), a navigation device, an Ultra Mobile PC (UMPC), or the like, and may also be used as a display screen of various products, such as a television, a laptop computer, a monitor, an advertisement board, an Internet of things (IoT) device, or the like. In addition, the electronic apparatus 1 according to an embodiment may be applied to a wearable device, such as a smart watch, a watch phone, a glasses-type display, and a head mounted display (HMD). In addition, the electronic apparatus 1 according to an embodiment may be used as a dashboard of a vehicle, a center fascia of a vehicle or a center information display (CID) arranged on a dashboard, a mirror display replacing a side mirror of a vehicle, and a display screen disposed on a back surface of a front seat as entertainment for a passenger in a back seat of a vehicle. For convenience of explanation, FIG. 1 shows that the electronic apparatus 1 is used as a smart phone.

Referring to FIG. 1, the electronic apparatus 1 may include a display area DA and a non-display area NDA outside the display area DA. The electronic apparatus 1 may provide an image through an array of a plurality of pixels, which are two-dimensionally arranged in the display area DA.

The non-display area NDA is an area which does not provide an image and may entirely surround the display area DA. A driver or the like for providing electrical signals or power to display elements arranged in the display area DA may be arranged in the non-display area NDA. A pad, which is an area to which an electronic device or a printed circuit board may be electrically connected, may be arranged in the non-display area NDA.

The display area DA may include a first display area DA1, a second display area DA2, and a third display area DA3. The second display area DA2 and the third display area DA3 are areas in which components for adding various functions to the electronic apparatus 1 are arranged, and the second display area DA2 may correspond to a component area.

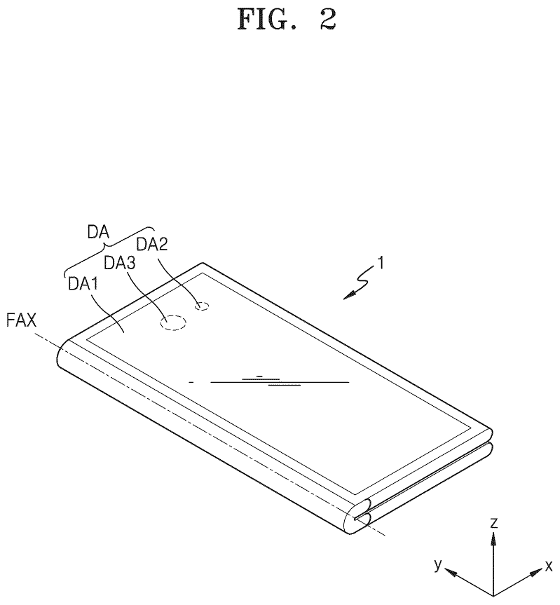

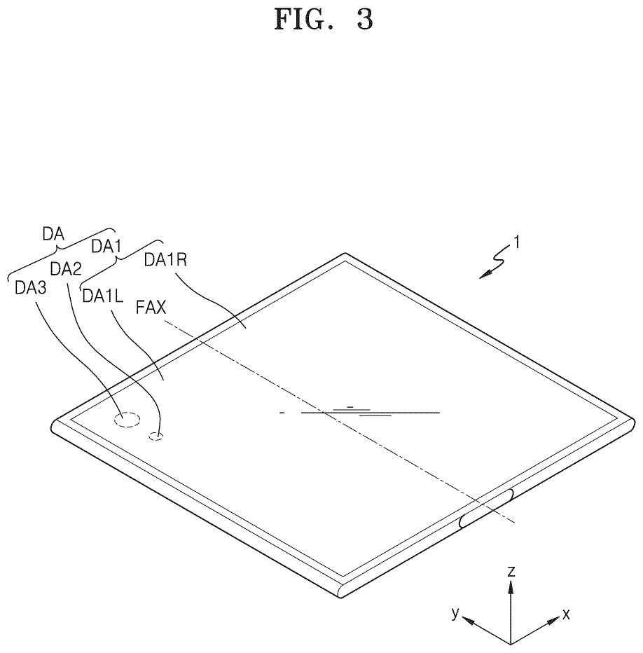

FIGS. 2 and 3 are schematic perspective views of a foldable electronic apparatus according to an embodiment. FIG. 2 shows a folded state of the foldable electronic apparatus, and FIG. 3 shows an unfolded state of the foldable electronic apparatus.

The electronic apparatus 1 according to an embodiment may be a foldable electronic apparatus. The electronic apparatus 1 may be folded around a folding axis FAX. The display area DA may be positioned at the outer side and/or the inner side of the electronic apparatus 1. In an embodiment, FIGS. 2 and 3 show that the display area DA is positioned in each of the outer side and the inner side of the electronic apparatus 1.

Referring to FIG. 2, the display area DA may be arranged at the outer side of the electronic apparatus 1. The outer side surface of the folded electronic apparatus 1 may include the display area DA, and the display area DA may include the first display area DA1 occupying most of the display area DA, the second display area DA2, and the third display area DA3, which have relatively small areas as compared to the first display area DA1.

Referring to FIG. 3, the display area DA may be arranged at the inner side of the electronic apparatus 1. The inner side surface of the unfolded electronic apparatus 1 may include the display area DA, and the display area DA may include the first display area DA1 occupying most of the display area DA, the second display area DA2, and the third display area DA3, which have relatively small areas as compared to the first display area DA1.

FIG. 3 shows that the first display area DA1 includes a left display area DA1L and a right display area DL1R, which are respectively positioned on the two sides of the folding axis FAX, and the second display area DA2 and the third display area DA3 are positioned inside the left display area DA1L, but the disclosure is not limited thereto. In another embodiment, the second display area DA2 and the third display area DA3 may be arranged in the right display area DL1R. In another embodiment, one of the second display area DA2 and the third display area DA3 may be arranged in the left display area DA1L, and the other one may be arranged in the right display area DL1R.

As shown in FIGS. 1, 2, and 3, the area of each of the second display area DA2 and the third display area DA3 may be less than the area of the first display area DA1. The second display area DA2 and the third display area DA3 may have different sizes (areas), and in this regard, FIGS. 1 and 2 show that the size (area) of the second display area DA2 is less than the size (area) of the third display area DA3.

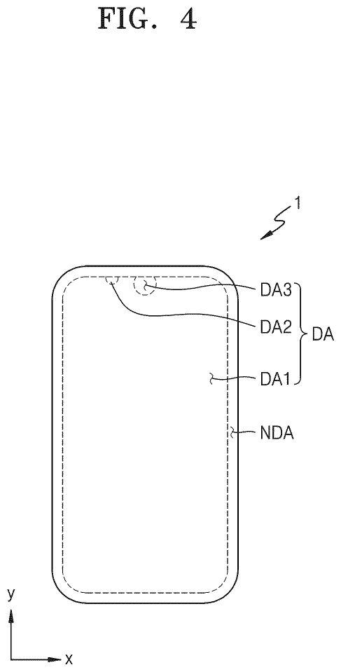

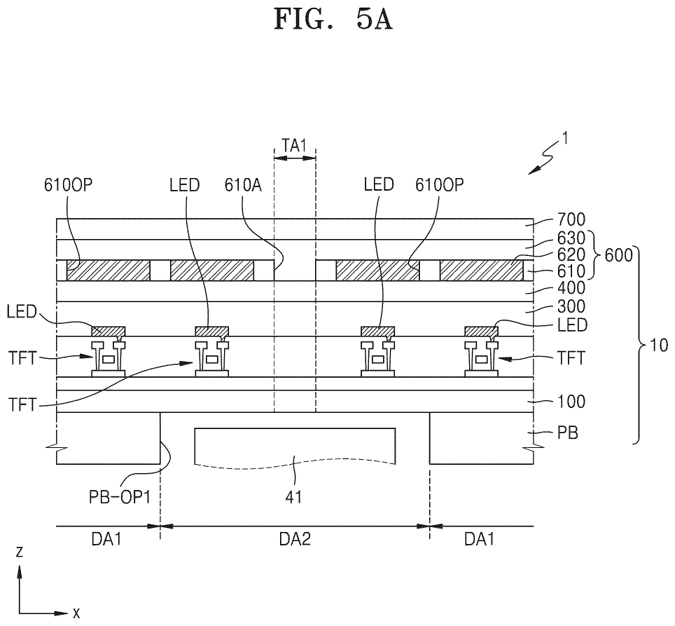

FIGS. 1, 2, and 3 show that each of the second display area DA2 and the third display area DA3 is entirely surrounded by the first display area DA1, but the disclosure is not limited thereto. FIG. 4 is a schematic plan view of an electronic apparatus according to another embodiment. As shown in FIG. 4, each of the second display area DA2 and the third display area DA3 is partially surrounded by the first display area DA1.

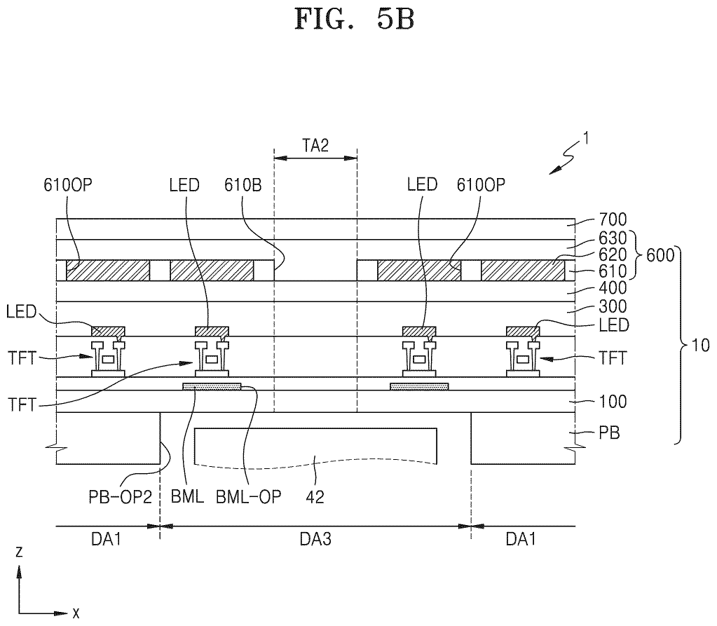

FIGS. 5A and 5B are cross-sectional views each illustrating a portion of an electronic apparatus according to an embodiment.

Referring to FIGS. 5A and 5B, the electronic apparatus 1 may include a display panel 10 and a component disposed on the lower surface of the display panel 10 to overlap the display panel 10. A first component 41 may be arranged in the second display area DA2, and a second component 42 may be arranged in the third display area DA3.

The display panel 10 may include a substrate 100, a thin-film transistor TFT disposed on the substrate 100, a display element (e.g., a light-emitting diode LED) electrically connected to the thin-film transistor TFT, an encapsulation layer 300 covering the display element, an input sensing layer 400, an anti-reflection layer 600, and a window 700.

The substrate 100 may include glass or a polymer resin. The substrate 100 including the polymer resin may be flexible, foldable, rollable, or bendable. The substrate 100 may have a multi-layered structure including a layer including the above-described polymer resin, and an inorganic layer (not shown).

A lower protective film PB may be disposed on the lower surface of the substrate 100. The lower protective film PB may be attached to the lower surface of the substrate 100. An adhesive layer may be between the lower protective film PB and the substrate 100. Alternatively, the lower protective film PB may be directly formed on the rear surface of the substrate 100, and in this case, an adhesive layer is not between the lower protective film PB and the substrate 100.

The lower protective film PB may support and protect the substrate 100. The lower protective film PB may have openings PB-OP1 and PB-OP2 respectively corresponding to the second display area DA2 and the third display area DA3. The lower protective film PB may include an organic insulating material such as polyethylene terephthalate (PET) or polyimide (PI).

The thin-film transistor TFT and the light-emitting diode LED, which is a display element electrically connected to the thin-film transistor TFT, may be disposed on the upper surface of the substrate 100. The light-emitting diode LED may be an organic light-emitting diode including an organic material. The organic light-emitting diode may emit red, green, or blue light.

The light-emitting diode LED may be an inorganic light-emitting diode including an inorganic material. The inorganic light-emitting diode may include a PN junction diode including materials based on inorganic semiconductors. When a voltage is applied to the PN junction diode in a forward direction, holes and electrons may be injected, and energy generated by recombination of the holes and electrons may be converted into light energy to emit a certain color of light. The above-described inorganic light-emitting diode may have a width of several to several hundred micrometers, or several to several hundred nanometers. In some embodiments, the light-emitting diode LED may include a quantum dot light-emitting diode. An emission layer of the light-emitting diode LED may include an organic material, an inorganic material, a quantum dot, an organic material and a quantum dot, or an inorganic material and a quantum dot.

The light-emitting diode LED may be electrically connected to the thin-film transistor TFT disposed therebelow. The thin-film transistor TFT and the light-emitting diode LED may be arranged in each of the first display area DA1, the second display area DA2, and the third display area DA3.

A transmission area may be positioned in the second display area DA2 and the third display area DA3. As shown in FIG. 5A, a transmission area (hereinafter referred to as a first transmission area TA1) between neighboring light-emitting diodes LED may be arranged in the second display area DA2. As shown in FIG. 5B, a transmission area (hereinafter referred to as a second transmission area TA2) between neighboring light-emitting diodes LED may be arranged in the third display area DA3.

The first transmission area TA1 and the second transmission area TA2 are respectively areas through which light emitted from the first component 41 and the second component 42 and/or light toward the first component 41 and the second component 42 may pass. In the display panel 10, the transmittance of each of the first transmission area TA1 and the second transmission area TA2 may be about 30% or more, about 40% or more, about 50% or more, about 60% or more, about 70% or more, about 75% or more, about 80% or more, about 85% or more, or about 90% or more.

The first component 41 and the second component 42 may respectively include a sensor, such as a proximity sensor, an illuminance sensor, an iris sensor, and a facial recognition sensor, and a camera (or an image sensor). Each of the first component 41 and the second component 42 may use light. For example, the first component 41 and the second component 42 may emit and/or receive light of infrared light, ultraviolet light, and visible light bands. A proximity sensor using infrared light may detect an object arranged close to the upper surface of the electronic apparatus 1, and an illuminance sensor may detect the brightness of light incident to the upper surface of the electronic apparatus 1. In addition, an iris sensor may capture an image of an iris or a person arranged on the upper surface of the electronic apparatus 1, and a camera may receive light related to an object arranged on the upper surface of the electronic apparatus 1.

The first component 41 and the second component 42 may be different from each other. In some embodiments, the first component 41 may include a sensor such as a proximity sensor, an illuminance sensor, an iris sensor, and a facial recognition sensor, and the second component 42 may include a camera (or an image sensor).

To prevent the function of the thin-film transistor TFT arranged in the second display area DA2 and/or the third display area DA3 from being reduced by light passing through the first transmission area TA1 and/or the second transmission area TA2, a light-blocking metal layer BML may be arranged between the substrate 100 and the thin-film transistor TFT. In an embodiment, FIG. 5B shows that the light-blocking metal layer BML is positioned in the third display area DA3. The light-blocking metal layer BML includes an opening BML-OP corresponding to the second transmission area TA2. As used herein, element A and element B “corresponding to” each other means their positions are aligned such that the elements are on top of each other or one element is in the area defined by the other element. The light-blocking metal layer BML may not be positioned in the first display area DA1 and the second display area DA2. In another embodiment, a light-blocking metal layer including an opening corresponding to the first transmission area TA1 may also be arranged in the second display area DA2.

The encapsulation layer 300 may cover the light-emitting diodes LED. The encapsulation layer 300 may include at least one inorganic encapsulation layer and at least one organic encapsulation layer.

The input sensing layer 400 may be formed on the encapsulation layer 300. The input sensing layer 400 may obtain coordinate information according to an external input, for example, a touch event of an object such as a finger or a stylus pen. The input sensing layer 400 may include a touch electrode and trace lines connected to the touch electrode. The input sensing layer 400 may sense an external input in a mutual-cap method or a self-cap method.

The anti-reflection layer 600 may reduce the reflectance of light (external light) incident from the outside toward the display panel 10. The anti-reflection layer 600 may include a light-blocking layer 610, color filters 620, and an overcoat layer 630. The light-blocking layer 610 may include openings 610OP overlapping the light-emitting diodes LED in the first display area DA1, the second display area DA2, and the third display area DA3, and the color filters 620 may be respectively arranged in the openings 610OP described above.

The light-blocking layer 610 may include an opening portion (hereinafter referred to as a transmission opening portion) defined by a sidewall of light-blocking layer and corresponding to a transmission area, for example, the first transmission area TA1 and the second transmission area TA2. The light-blocking layer 610 may include a first transmission opening portion corresponding to the first transmission area TA1 provided in the second display area DA2 as shown in FIG. 5A and a second transmission opening portion 610B corresponding to the second transmission area TA2 provided in the third display area DA3 as shown in FIG. 5B.

The overcoat layer 630 may include a colorless transmissive material, and a portion of the overcoat layer 630 may at least partially fill the first transmission opening portion 610A and the second transmission opening portion 610B.

The window 700 may be disposed on the anti-reflection layer 600. The window 700 may be coupled to the anti-reflection layer 600 through an adhesive layer such as an optically clean adhesive. The window 700 may include a glass material or a plastic material. The glass material may include ultra-thin glass. The plastic material may include polyethersulfone, polyacrylate, polyetherimide, polyethylene naphthalate, polyethylene terephthalate, polyphenylene sulfide, polyarylate, polyimide, polycarbonate, cellulose acetate propionate, or the like.

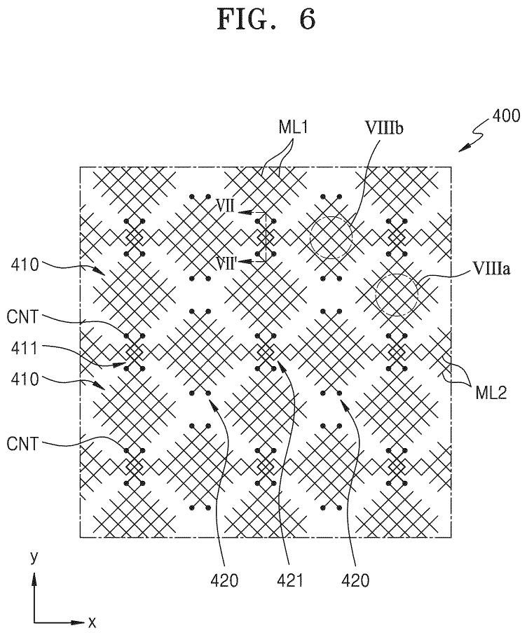

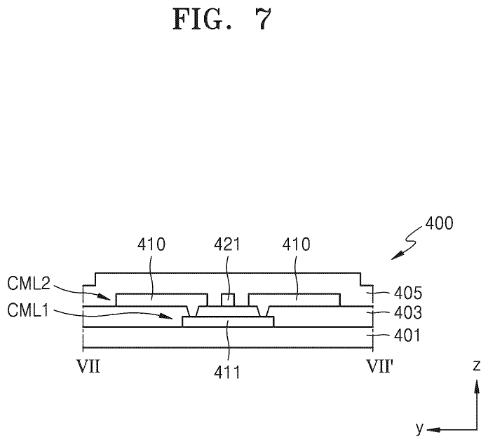

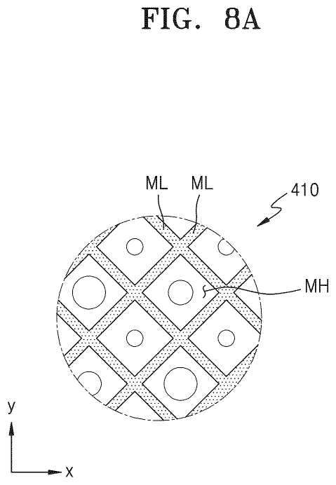

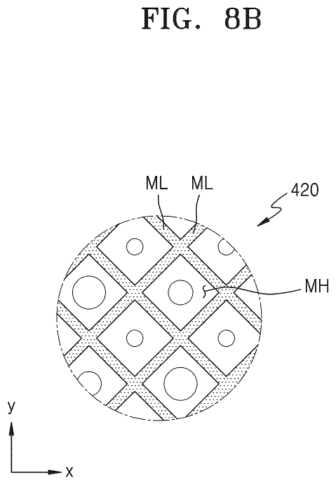

FIG. 6 is a plan view of an input sensing layer of a display apparatus according to an embodiment, FIG. 7 is a cross-sectional view of the input sensing layer of FIG. 6, taken along a line VII-VII′ in FIG. 6, FIG. 8A is an enlarged plan view of VIIIa of FIG. 6, and FIG. 8B is an enlarged plan view of VIIIb of FIG. 6.

The input sensing layer 400 may include a plurality of touch electrodes. In an embodiment, FIG. 6 shows that the touch electrodes include first touch electrodes 410 and second touch electrodes 420. The first touch electrodes 410 and the second touch electrodes 420 may be arranged in a display area to cross each other.

The first touch electrodes 410 may be arranged in a y direction, and the second touch electrodes 420 may be arranged in an x direction crossing the y direction. The first touch electrodes 410 arranged in the y direction may be connected to each other by a first connection electrode 411 between the neighboring first touch electrodes 410. The second touch electrodes 420 arranged in the x direction may be connected to each other by a second connection electrode 421 between the neighboring second touch electrodes 420.

The first touch electrode 410 and the second touch electrode 420 may have a conductive mesh pattern as shown in FIGS. 6, 8A, and 8B. For example, the conductive mesh pattern of the first touch electrode 410 may include a conductive line (hereinafter referred to as a first conductive line ML1), and the conductive mesh pattern of the second touch electrode 420 may include a conductive line (hereinafter referred to as a second conductive line ML2) that is insulated from the first conductive line ML1. The first conductive line ML1 and the second conductive line ML2 may include molybdenum (Mo), mendelevium (Mb), silver (Ag), titanium (Ti), copper (Cu), aluminum (AI), and alloys thereof.

Because each of the first touch electrode 410 and the second touch electrode 420 has a conductive mesh pattern, each of the first touch electrode 410 and the second touch electrode 420 may include a hole (hereinafter referred to as a mesh hole MH), as shown in FIGS. 8A and 8B. The mesh holes MH may be defined by being entirely surrounded by respective corresponding conductive lines and may be arranged to be spaced apart from each other.

Similarly to the first touch electrode 410 and the second touch electrode 420, the first connection electrode 411 and a second connection electrode 421 may also include a conductive line in a conductive mesh pattern. The conductive line of each of the first connection electrode 411 and the second connection electrode 421 may also include a mesh hole, as shown in FIGS. 8A and 8B.

The input sensing layer 400 may include a first touch insulating layer 401, a first conductive layer CML1, a second touch insulating layer 403, a second conductive layer CML2, and a third touch insulating layer 405, as shown in FIG. 7. The first conductive layer CML1 may include the first connection electrode 411, and the second conductive layer CML2 may include the first touch electrode 410, the second touch electrode 420, and the second connection electrode 421. In another embodiment, any one of the first touch electrode 410 and the second touch electrode 420 may be provided in the first conductive layer CML1, and the other one may be provided in the second conductive layer CML2. Each of the first touch insulating layer 401, the second touch insulating layer 403, and the third touch insulating layer 405 may include an insulating material. In an embodiment, each of the first touch insulating layer 401, the second touch insulating layer 403, and the third touch insulating layer 405 may include an inorganic insulating material, such as silicon oxide, silicon nitride, and/or silicon oxynitride. In another embodiment, at least any one of the first touch insulating layer 401, the second touch insulating layer 403, and the third touch insulating layer 405 may include an organic insulating material.

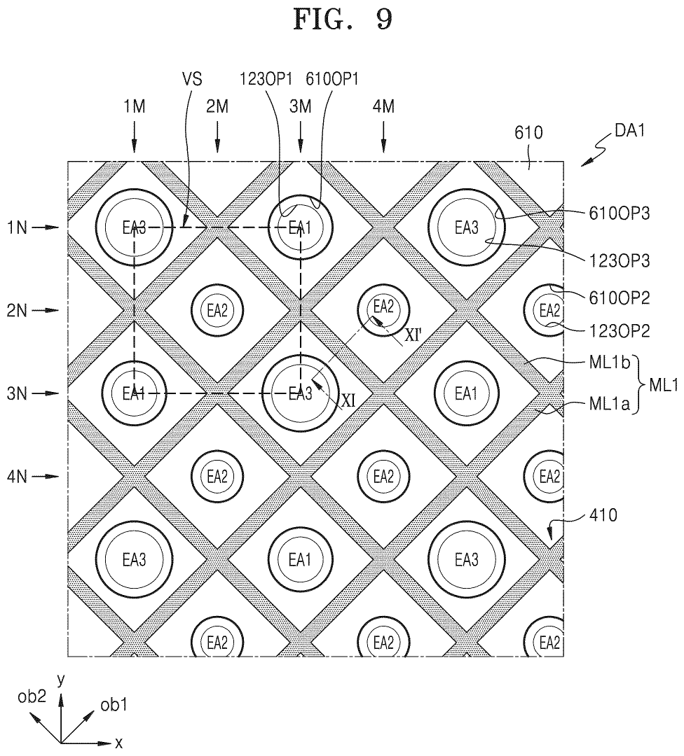

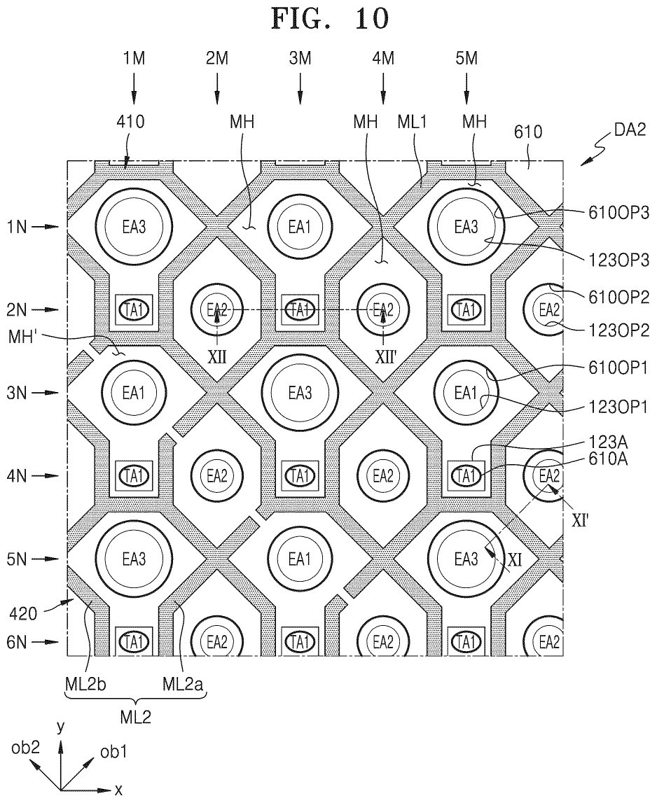

FIG. 9 is a plan view illustrating a first display area of a display panel according to an embodiment, and FIG. 10 is a plan view illustrating a second display area of a display panel according to an embodiment.

Referring to FIG. 9, first to third emission areas EA1, EA2, and EA3 may be arranged in the first display area DA1. The first to third emission areas EA1, EA2, and EA3 may emit different colors of light by using light-emitting diodes. One of the first to third emission areas EA1, EA2, and EA3 may correspond to a red emission area, another one may correspond to a green emission area, and the remaining one may correspond to a blue emission area.

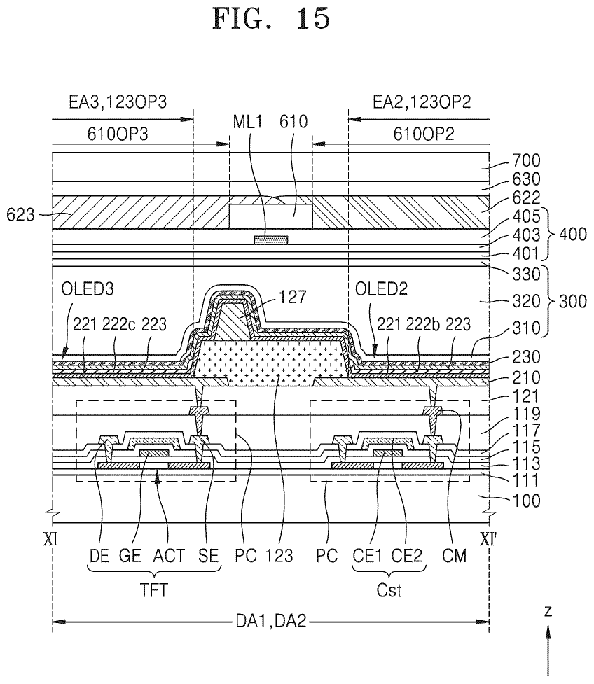

The sizes of the first to third emission areas EA1, EA2, and EA3 may be respectively defined by a plurality of openings provided in a bank layer (123 refer to FIG. 15). For example, the first emission area EA1 may be defined by a first opening 123OP1 of the bank layer 123, the second emission area EA2 may be defined by a second opening 123OP2 of the bank layer 123, and the third emission area EA3 may be defined by a third opening 123OP3 of the bank layer 123.

The first to third emission areas EA1, EA2, and EA3 may be arranged in a pentile™ type, for example, a diamond pentile™ type. The third emission areas EA3 and the first emission areas EA1 may be alternately arranged in a first row 1N in an x direction, the second emission areas EA2 may be arranged to be spaced apart from each other by a certain distance in a second row 2N adjacent to the first row 1N, the first emission areas EA1 and the third emission areas EA3 may be alternately arranged in a third row 3N adjacent to the second row 2N, the second emission areas EA2 may be arranged to be spaced apart from each other by a certain distance in a fourth row 4N adjacent to the third row 3N, and the arrangement of emission areas is repeated up to an N-th row. At this time, the sizes (or widths) of the third emission area EA3 and the first emission area EA1 may be greater than the size (or width) of the second emission area EA2.

The third emission area EA3 and the first emission area EA1 arranged in the first row 1N may be arranged to alternate with the second emission area EA2 arranged in the second row 2N. Accordingly, the third emission areas EA3 and the first emission areas EA1 may be alternately arranged in a first column 1M, the second emission areas EA2 may be arranged to be spaced apart from each other by a certain distance in a second column 2M adjacent to the first column 1M, the first emission areas EA1 and the third emission areas EA3 may be alternately arranged in a third column 3M adjacent to the second column 2M, the second emission areas EA2 may be arranged to be spaced apart from each other by a certain distance in a fourth column 4M adjacent to the third column 3M, and the arrangement of the emission areas is repeated up to an M-th column.

When the arrangement structure of the emission areas is expressed differently, it may be expressed that the first emission area EA1 is arranged at first and third vertices facing each other among vertices of a virtual quadrangle VS, in which a central point of the second emission area EA2 is a central point of the quadrangle, and the third emission area EA3 is arranged at second and fourth vertices, which are the remaining vertices. At this time, the virtual quadrangle VS may be variously changed, such as a rectangle, a rhombus, a square, or the like.

The arrangement structure of the emission areas may be referred to as a pentile™ matrix structure or a pentile™ structure, and high resolution may be implemented with a small number of emission areas by applying rendering driving that expresses colors by sharing adjacent emission areas.

Referring to FIG. 10, the first to third emission areas EA1, EA2, and EA3 emitting different lights may be arranged in the second display area DA2. The sizes of the first to third emission areas EA1, EA2, and EA3 may be respectively defined by the first to third openings 123OP1, 123OP2, and 123OP3 of the bank layer 123, as described above.

The first display area DA1 and the second display area DA2 may have the same resolution. For example, the arrangement, opening ratio, and/or number of the first to third emission areas EA1, EA2, and EA3 in the second display area DA2 may be the same as the arrangement, opening ratio, and/or number of the first to third emission areas EA1, EA2, and EA3 in the first display area DA1 per same area. Because each of emission areas, for example, the first to third emission areas EA1, EA2, and EA3, includes a light-emitting diode, the arrangement and/or number of emission areas being the same may indicate that the arrangement and/or number of light-emitting diodes are the same. For example, the arrangement and/or number of light-emitting diodes arranged in the first display area DA1 may be the same as the arrangement and/or number of light-emitting diodes arranged in the second display area DA2 per same area.

The second display area DA2 may include the first transmission area TA1, unlike the first display area DA1. The first transmission area TA1 may be arranged between neighboring emission areas. In some embodiments, the first transmission area TA1 may be arranged in one of two neighboring rows in a row direction (x direction). For example, FIG. 10 depicts the first transmission area TA1 in the second row 2N, the fourth row 4N, and the sixth row 6N. Additionally, the first transmission area TA1 may be arranged in one of two neighboring columns in a column direction (y direction). For example, as shown in FIG. 10, the first transmission area TA1 may be arranged in the first column 1M, the third column 3M, and the fifth column 5M. As described above, the bank layer 123 may include a light-blocking material, and accordingly, the bank layer 123 may include a bank opening portion 123A corresponding to the first transmission area TA1, as shown in FIG. 10.

Referring to FIGS. 9 and 10, each emission area may be surrounded by a conductive line of a touch electrode. As shown in FIGS. 9 and 10, a touch electrode, for example, the first touch electrode 410, may include a conductive mesh pattern including the first conductive line ML1. The first conductive line ML1 may include a first sub-conductive line ML1a extending in a first diagonal direction ob1 (a direction forming acute angles with an x direction and a y direction), and a second sub-conductive line ML1b extending in a second diagonal direction ob2 (a direction crossing the first diagonal direction ob1). A plurality of mesh holes MH may be formed by the intersection structure of the first sub-conductive lines ML1a and the second sub-conductive lines ML1b, which are integrally formed. Each of the mesh holes MH has a closed-loop shaped-outline, and in a plan view, the mesh holes MH may be spaced apart from each other and spatially separated from each other.

According to some embodiments, as shown in FIG. 10, the second touch electrode 420 may be arranged in the second display area DA2. The second touch electrode 420 may include a conductive mesh pattern including a second conductive line ML2. For example, the second conductive line ML2 may include a first sub-conductive line ML2a extending in the first diagonal direction ob1 and a second sub-conductive line ML2b extending in the second diagonal direction ob2. The plurality of mesh holes MH may be formed by the intersection structure of the first sub-conductive lines ML2a and the second sub-conductive lines ML2b of the second conductive line ML2, which are integrally formed. Each of the mesh holes MH has a closed-loop-shaped outline, and in a plan view, the mesh holes MH may be spaced apart from each other and spatially separated from each other.

The first touch electrode 410 and the second touch electrode 420 may be electrically insulated from each other, and in this regard, FIG. 10 shows that the first touch electrode 410 and the second touch electrode 420 are physically spaced apart from each other. An emission area arranged in a separation space between the first touch electrode 410 and the second touch electrode 420, for example, each of the first emission area EA1 and the second emission area EA2 shown in FIG. 10, may be positioned in a hole (hereinafter referred to as a separation hole MH′) formed between a portion of the second conductive line ML2 and a portion of the first conductive line ML1, which are adjacent to each other. The separation hole MH' may be defined by a portion of the first conductive line ML1 and a portion of the second conductive line ML2, and neighboring separation holes MH′ may be spatially connected to each other in a plan view.

In the second display area DA2, the first transmission area TA1 may be positioned in the same mesh hole MH as any one emission area. In this regard, FIG. 10 shows that, in a plan view, the first emission area EA1 and the first transmission area TA1 are positioned in the same mesh hole MH, and the third emission area EA3 and the first transmission area TA1 are positioned in the same mesh hole MH. The first emission area EA1 and the first transmission area TA1, which are positioned in the same mesh hole MH, are surrounded by a conductive line of a touch electrode, for example, a portion of the first conductive line ML1, in a plan view. Similarly, the third emission area EA3 and the first transmission area TA1, which are positioned in the same mesh hole MH, are surrounded by a conductive line of a touch electrode, for example, a portion of the first conductive line ML1, in a plan view.

As the first transmission area TA1 is arranged while maintaining the same resolution (e.g., the number and/or area of emission areas per same area) of the first display area DA1 and the second display area DA2, the size and planar shape of each mesh hole MH positioned in the second display area DA2 may be different from the size and planar shape of each mesh hole MH positioned in the first display area DA1. In an embodiment, the second emission area EA2 shown in FIG. 10 is an area that does not include the first transmission area TA1 in the corresponding mesh hole MH, the size (or width) of the mesh hole MH corresponding to the second emission area EA2 of the second display area DA2 may be less than the size (or width) of the mesh hole MH corresponding to the second emission area EA2 of the first display area DA1 shown in FIG. 9.

The light-blocking layer 610 is arranged on the touch electrodes of FIGS. 9 and 10. The light-blocking layer 610 covers the conductive lines of the touch electrodes (e.g., the first touch electrode 410 and the second touch electrode 420), but may include openings or opening portions corresponding to emission areas and the first transmission area TA1. In this regard, FIGS. 9 and 10 show that the light-blocking layer 610 includes first to third openings 610OP1, 610OP2, and 610OP3 respectively corresponding to the first to third emission areas EA1, EA2, and EA3 positioned in the first display area DA1 and the second display area DA2, and the first transmission opening portion 610A corresponding to the first transmission area TA1.

In a plan view, the first to third openings 610OP1, 610OP2, and 610OP3 of the light-blocking layer 610 may be spaced apart from each other and may respectively align with the first to third openings 123OP1, 123OP2, and 123OP3 of the bank layer 123, which respectively define the first to third emission areas EA1, EA2, and EA3. The sizes (or widths) of the first to third openings 610OP1, 610OP2, and 610OP3 of the light-blocking layer 610 may be greater than the sizes (or widths) of the first to third openings 123OP1, 123OP2, and 123OP3 of the bank layer 123, which respectively define the first to third emission areas EA1, EA2, and EA3.

In a plan view, the first transmission opening portion 610A of the light-blocking layer 610 may align with the bank opening portion 123A of the bank layer 123. The size (or width) of the first transmission opening portion 610A of the light-blocking layer 610 may be less than the size (or width) of the bank opening portion 123A of the bank layer 123, which corresponds to the first transmission area TA1.

In an embodiment, at least a portion of the sidewall defining the first transmission opening portion 610A of the light-blocking layer 610 may be curved. In particular, as shown in FIG. 10, the first transmission opening portion 610A of the light-blocking layer 610 may have an oval shape in plan view. The bank opening portion 123A of the bank layer 123 may have a polygonal shape. In particular, as shown in FIG. 10, the bank opening portion 123A of the bank layer 123 may have a rectangular shape.

When the bank opening portion 123A of the bank layer 123 and the first transmission opening portion 610A of the light-blocking layer 610 both have rectangular shapes, a phenomenon in which external light reflection is visible may occur. This phenomenon occurs because when the bank opening portion 123A of the bank layer 123 and the first transmission opening portion 610A of the light-blocking layer 610 have rectangular shapes, light is reflected and becomes visible. When the bank opening portion 123A of the bank layer 123 and the first transmission opening portion 610A of the light-blocking layer 610 have rectangular shapes, the transmittance of light may be 0.7%. When the bank opening portion 123A of the bank layer 123 and the first transmission opening portion 610A of the light-blocking layer 610 have oval shapes, although the phenomenon in which external light reflection is visible is prevented, the areas of the bank opening portion 123A and the first transmission opening portion 610A are less than the areas in the case of being rectangular shapes, and thus the transmittance of light may be reduced to 0.54%.

In an embodiment, when at least a portion of the first transmission opening portion 610A of the light-blocking layer 610 is curved, and the bank opening portion 123A of the bank layer 123 has a polygonal shape, the phenomenon in which external light reflection is visible may be prevented. At the same time, the transmittance of light may be secured. As at least a portion of the first transmission opening portion 610A of the light-blocking layer 610 is curved, the phenomenon in which light is visible due to external light reflection may be prevented, and as the bank opening portion 123A of the bank layer 123 has a polygonal shape, the area of the bank opening portion 123A is secured, and thus the transmittance of light may be secured. In particular, when the first transmission opening portion 610A of the light-blocking layer 610 has an oval shape, and the bank opening portion 123A of the bank layer 123 has a rectangular shape, the phenomenon in which light is reflected and external light reflection becomes visible may not occur, and the transmittance of light is 0.57%, which is higher than the transmittance of light in the case where the first transmission opening portion 610A of the light-blocking layer 610 and the bank opening portion 123A of the bank layer 123 have oval shapes.

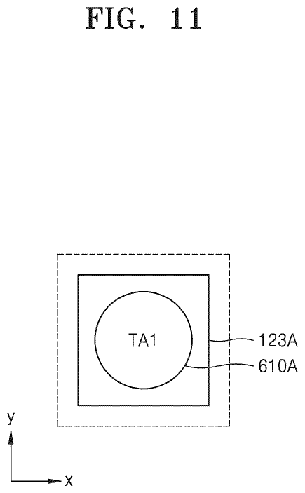

FIGS. 11 to 14 are plan views each showing a first transmission opening portion of a light-blocking layer and a bank opening portion of a bank layer, according to embodiments.

Referring to FIG. 11, the first transmission opening portion 610A of the light-blocking layer 610 may have a circular shape (i.e., by the sidewall of the first transmission opening portion 610A curving to form a circle), and the bank opening portion 123A of the bank layer 123 may have a rectangular shape. The bank opening portion 123A of the bank layer 123 may be arranged to surround the first transmission opening portion 610A of the light-blocking layer 610. However, the disclosure is not limited thereto. In another embodiment, the bank opening portion 123A of the bank layer 123 may also have various polygonal shapes, such as a pentagonal shape, a hexagonal shape, or the like, while surrounding the first transmission opening portion 610A of the light-blocking layer 610.

As the first transmission opening portion 610A of the light-blocking layer 610 has a circular shape, and the bank opening portion 123A of the bank layer 123 has a rectangular shape while surrounding the first transmission opening portion 610A of the light-blocking layer 610, the phenomenon in which external light reflection is visible may be prevented, and the transmittance of light may be secured, thereby securing the quality and reliability of a display panel.

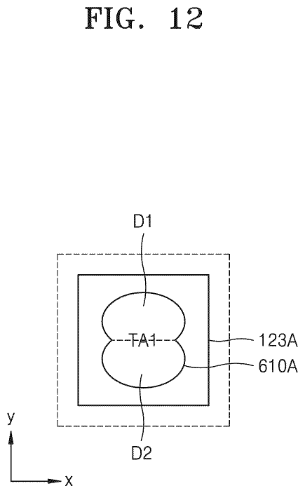

Referring to FIG. 12, the first transmission opening portion 610A of the light-blocking layer 610 may include a first portion D1 having a shape of at least a portion of a circle or an oval, and a second portion D2 having a shape of at least a portion of a circle or an oval. The light-blocking layer 610 may include the first portion D1 and the second portion D2, so that the edge of the first transmission opening portion 610A of the light-blocking layer 610 may be curved.

The bank opening portion 123A of the bank layer 123 may be arranged to surround the first transmission opening portion 610A of the light-blocking layer 610 and may have a rectangular shape. However, the disclosure is not limited thereto. In another embodiment, the bank opening portion 123A of the bank layer 123 may also have various polygonal shapes, such as a pentagonal shape, a hexagonal shape, or the like, while surrounding the first transmission opening portion 610A of the light-blocking layer 610.

The first transmission opening portion 610A of the light-blocking layer 610 may include the first portion D1 having a shape of at least a portion of a circle or an oval, and a second portion D2 having a shape of at least a portion of a circle or an oval, so that the sidewall defining the first transmission opening portion 610A of the light-blocking layer 610 is curved, and the bank opening portion 123A of the bank layer 123 has a rectangular shape surrounding the first transmission opening portion 610A of the light-blocking layer 610, and thus the phenomenon in which external light reflection is visible may be prevented, and the transmittance of light may be secured, thereby securing the quality and reliability of a display panel.

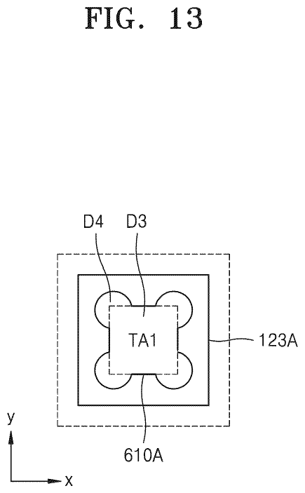

Referring to FIG. 13, the first transmission opening portion 610A of the light-blocking layer 610 may include a third portion D3 having a shape of an imaginary rectangle and a plurality of fourth portions D4 respectively arranged at vertices of the imaginary rectangle of the third portion D3. The fourth portions D4 have a shape of at least a portion of a circle or an oval, and the third portion D3 may be defined by a wall extending in a straight line. The first transmission opening portion 610A of the light-blocking layer 610 may be provided to include the third portion D3 and the plurality of fourth portions D4, so that at least a portion of the sidewall defining the first transmission opening portion 610A of the light-blocking layer 610 may be curved.

The bank opening portion 123A of the bank layer 123 may be arranged to surround the first transmission opening portion 610A of the light-blocking layer 610 and may have a rectangular shape. However, the disclosure is not limited thereto. In another embodiment, the bank opening portion 123A of the bank layer 123 may have any of various polygonal shapes, such as a pentagonal shape, a hexagonal shape, or the like, while surrounding the first transmission opening portion 610A of the light-blocking layer 610.

The first transmission opening portion 610A of the light-blocking layer 610 includes the third portion D3 and the plurality of fourth portions D4 having a shape of at least a portion of a circle or an oval, so that at least a portion of the sidewall defining the first transmission opening portion 610A of the light-blocking layer 610 is curved, and the bank opening portion 123A of the bank layer 123 has a polygonal shape while surrounding the first transmission opening portion 610A of the light-blocking layer 610, and thus the phenomenon in which external light reflection is visible may be prevented, and the transmittance of light is secured, thereby securing the quality and reliability of a display panel.

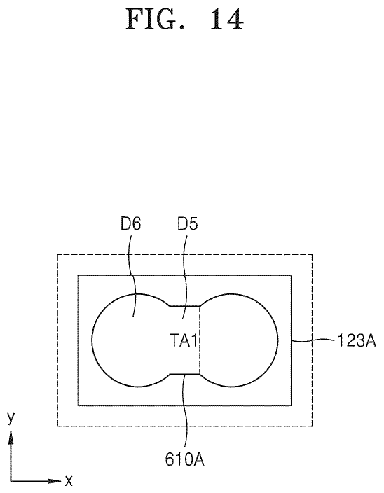

Referring to FIG. 14, the first transmission opening portion 610A of the light-blocking layer 610 may include a fifth portion D5 having a rectangular shape and a plurality of sixth portions D6 respectively arranged on both corners of the fifth portion D5 and having a shape of at least a portion of a circle or an oval. In particular, because the plurality of sixth portions D6 are respectively arranged at both corners of the fifth portion D5, the plurality of sixth portions D6 may be two sixth portions D6. The first transmission opening portion 610A of the light-blocking layer 610 may be provided to including the fifth portion D5 and the plurality of sixth portions D6, so that at least a portion of the sidewall defining the first transmission opening portion 610A of the light-blocking layer 610 may be curved.

The bank opening portion 123A of the bank layer 123 may be arranged to surround the first transmission opening portion 610A of the light-blocking layer 610 and may have a rectangular shape. However, the disclosure is not limited thereto. In another embodiment, the bank opening portion 123A of the bank layer 123 may also have various polygonal shapes, such as a pentagonal shape, a hexagonal shape, or the like, while surrounding the first transmission opening portion 610A of the light-blocking layer 610.

The first transmission opening portion 610A of the light-blocking layer 610 includes the fifth portion D5 and the plurality of sixth portions D6 has a circular shape or an oval shape, so that at least a portion of the sidewall defining the first transmission opening portion 610A of the light-blocking layer 610 is curved, and the bank opening portion 123A of the bank layer 123 has a rectangular shape while surrounding the first transmission opening portion 610A of the light-blocking layer 610. With the sidewall of the first transmission opening portion 610A being curved, the phenomenon in which external light reflection is visible may be prevented and the transmittance of light is secured, thereby securing the quality and reliability of a display panel.

FIG. 15 is a cross-sectional view of a display panel according to an embodiment, taken along a line XI-XI′ of FIGS. 9 and 10. FIG. 15 shows a cross-sectional structure of neighboring emission areas in the first display area DA1 and the second display area DA2, which shows the second emission area EA2 and the third emission area EA3. In FIG. 15, a case in which the second emission area EA2 of the display panel emits light by using a second organic light-emitting diode OLED2, and the third emission area EA3 emits light by using a third organic light-emitting diode OLED3 is described.

Referring to FIG. 15, the second organic light-emitting diode OLED2 and the third organic light-emitting diode OLED3 are formed above the substrate 100. The substrate 100 may include a glass material or a polymer resin, and when the substrate 100 includes the polymer resin, the substrate 100 may include a stacked structure including a base layer including the polymer resin and a barrier layer including an inorganic insulating material.

A buffer layer 111 is disposed on the substrate 100. The buffer layer 111 may reduce or block penetration of foreign materials, moisture, or external air from a lower portion of the substrate 100. The buffer layer 111 may include an inorganic insulating material, such as silicon oxide, silicon oxynitride, and silicon nitride, and may include a single-layered structure or a multi-layered structure, each including the material stated above.

The second organic light-emitting diode OLED2 and the third organic light-emitting diode OLED3 may be respectively electrically connected to pixel circuits PC. The second organic light-emitting diode OLED2 may be electrically connected to a pixel circuit PC between the substrate 100 and the second organic light-emitting diode OLED2, and the third organic light-emitting diode OLED3 may be electrically connected to a pixel circuit PC between the substrate 100 and the third organic light-emitting diode OLED3.

Each pixel circuit PC may include the thin-film transistor TFT and a storage capacitor Cst. The thin-film transistor TFT may include a semiconductor layer Act, a gate electrode GE overlapping the channel area of the semiconductor layer Act, a source electrode SE, and a drain electrode DE, which are respectively connected to a source area and a drain area of the semiconductor layer Act. A gate insulating layer 113 may be between the semiconductor layer Act and the gate electrode GE, and a first interlayer insulating layer 115 and a second interlayer insulating layer 117 may be between the gate electrode GE and the source electrode SE or between the gate electrode GE and the drain electrode DE.

The storage capacitor Cst may be arranged to overlap the thin-film transistor TFT. The storage capacitor Cst may include a lower electrode CE1 and an upper electrode CE2, which overlap each other. In some embodiments, the gate electrode GE of the thin-film transistor TFT may include the lower electrode CE1 of the storage capacitor Cst. The first interlayer insulating layer 115 may be between the lower electrode CE1 and the upper electrode CE2.

The semiconductor layer Act may include polysilicon. In some embodiments, the semiconductor layer Act may include amorphous silicon. In some embodiments, the semiconductor layer Act may include an oxide semiconductor of at least one material selected from a group consisting of indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer Act may include a channel area, a source area, and a drain area, wherein the source area and the drain area are doped with impurities.

The gate insulating layer 113 may include an inorganic insulating material such as silicon oxide, silicon oxynitride, and silicon nitride, and may have a single-layered structure or a multi-layered structure, each including the above material.

The gate electrode GE or the lower electrode CE1 may include a low-resistance conductive material, such as Mo, Al, Cu, and/or Ti, and may include a single-layered structure or a multi-layered structure, each including the above material.

The first interlayer insulating layer 115 may include an inorganic insulating material such as silicon oxide, silicon oxynitride, and silicon nitride, and may have a single-layered structure or a multi-layered structure, each including the above material.

The upper electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may have a single-layered or a multi-layered structure, each including the material stated above.

The second interlayer insulating layer 117 may include an inorganic insulating material such as silicon oxide, silicon oxynitride, and silicon nitride, and may have a single-layered structure or a multi-layered structure, each including the above material.

The source electrode SE and/or the drain electrode DE may include Al, Pt, Pd, Ag, Mg, Au, Ni, Nd, Ir, Cr, Ca, Mo, Ti, W, and/or Cu, and may have a single-layered structure or a multi-layered structure, each including the above material. For example, the source electrode SE and/or the drain electrode DE may have a three-layered structure of a titanium layer/aluminum layer/titanium layer.

A first organic insulating layer 119 may be positioned on the thin-film transistor TFT, and the thin-film transistor TFT may be electrically connected to a first electrode 210 of a corresponding organic light-emitting diode through a connection electrode CM disposed on the first organic insulating layer 119. The connection electrode CM may be connected to the thin-film transistor TFT through a contact hole of the first organic insulating layer 119, and the first electrode 210 may be connected to the connection electrode CM through a contact hole of a second organic insulating layer 121.

The first organic insulating layer 119 and/or the second organic insulating layer 121 may include an organic insulating material, such as benzocyclobutene (BCB), polyimide, hexamethyldisiloxane (HMDSO), or the like. In some embodiments, the connection electrode CM and the second organic insulating layer 121 may be omitted, and in this case, the first electrode 210 may be directly connected to the thin-film transistor TFT through the contact hole of the first organic insulating layer 119.

The second organic light-emitting diode OLED2 may include an overlapping structure of the first electrode 210, an emission layer (hereinafter referred to as a second emission layer 222b), and a second electrode 230. The third organic light-emitting diode OLED3 may include an overlapping structure of the first electrode 210, an emission layer (hereinafter referred to as a third emission layer 222c), and the second electrode 230. A first functional layer 221 and/or a second functional layer 223 may be included between the first electrode 210 and the second electrode 230.

The first electrode 210 may be positioned on the second organic insulating layer 121. The first electrode 210 may include a reflective film including Ag, Mg, Al, Pt, Pd, Au, Ni, Nd, Ir, Cr, or a compound thereof. The first electrode 210 may include a reflective film including the above material and a transparent conductive film disposed above or/and below the reflective film. The transparent conductive film may include indium tin oxide (ITO), indium zinc oxide (IZO), zinc oxide (ZnO), indium oxide (In₂O₃), indium gallium oxide (IGO), or aluminum zinc oxide (AZO). In an embodiment, the first electrode 210 may have a three-layered structure of an ITO layer/Ag layer/ITO layer.

The bank layer 123 may include a light-blocking material. The bank layer 123 may have, for example, a black color. For example, the bank layer 123 may include a polyimide (PI)-based binder, and a pigment in which red, green, and blue colors are mixed with each other. Alternatively, the bank layer 123 may include a cardo-based binder resin, and a mixture of a lactam black pigment and a blue pigment. Alternatively, the bank layer 123 may include carbon black. The bank layer 123 may prevent reflection of external light together with the anti-reflection layer 600 to be described below and may improve the contrast of the display panel.

A spacer 127 may be disposed on the bank layer 123. The spacer 127 may include a material different from that of the bank layer 123. For example, the bank layer 123 and the spacer 127 may include different materials, for example, the bank layer 123 includes a negative photosensitive material, and the spacer 127 includes a positive photosensitive material, and may be formed through separate mask processes.

The second emission layer 222b and the third emission layer 222c may be positioned to respectively correspond to the second opening 123OP2 and the third opening 123OP3 of the bank layer 123 and may overlap the first electrode 210. The second emission layer 222b and the third emission layer 222c may each include a polymer organic material or a low-molecular-weight organic material, which emits a certain color of light, and may emit different colors of light. The first functional layer 221 and the second functional layer 223 may respectively be formed below and on the second emission layer 222b and the third emission layer 222c.

The first functional layer 221 may include a hole transport layer (HTL) and/or a hole injection layer (HIL). The second functional layer 223 may include an electron transport layer (ETL) and/or an electron injection layer (EIL). The first functional layer 221 and/or the second functional layer 223 may be entirely formed on the substrate 100, unlike the second emission layer 222b and the third emission layer 222c. In other words, the first functional layer 221 and/or the second functional layer 223 may cover the first display area DA1 and the second display area DA2.

The second electrode 230 may include a material having a relatively high work function. For example, the second electrode 230 may be formed as a transparent thin film including Ag and Mg.

The encapsulation layer 300 may cover emission areas, for example, the second organic light-emitting diode OLED 2 and the third organic light-emitting diode OLED3. In an embodiment, the encapsulation layer 300 may include a first inorganic encapsulation layer 310, a second inorganic encapsulation layer 330, and an organic encapsulation layer 320 between the first inorganic encapsulation layer 310 and the second inorganic encapsulation layer 330.

Each of the first inorganic encapsulation layer 310 and the second inorganic encapsulation layer 330 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The organic encapsulation layer 320 may include a polymer-based material. The polymer-based material may include an acrylic resin, an epoxy resin, polyimide, polyethylene, or the like. For example, the organic encapsulation layer 320 may include an acrylic resin, for example, polymethyl methacrylate, polyacrylic acid, or the like. The organic encapsulation layer 320 may be formed by curing a monomer or coating a polymer.

The input sensing layer 400 may include the first touch insulating layer 401 on the encapsulation layer 300, the second touch insulating layer 403 on the first touch insulating layer 401, and the third touch insulating layer 405 on the second touch insulating layer 403. The input sensing layer 400 includes a touch electrode, but the touch electrode may include a conductive line disposed on the second touch insulating layer 403 and below the third touch insulating layer 405. In this regard, in an embodiment, FIG. 15 shows the first conductive line ML1.

The conductive line, for example, the first conductive line ML1 in FIG. 15, may include Mo, Mb, Ag, Ti, Cu, Al, and alloys thereof. The first conductive line ML1 may be covered by the light-blocking layer 610 having a greater width than the first conductive line ML1.

The light-blocking layer 610 may include a second opening 610OP2 and a third opening 610OP3 respectively overlapping the second emission area EA2 and the third emission area EA3. The second opening 610OP2 and the third opening 610OP3 may have greater sizes (or widths) than that of the second opening 123OP2 and the third opening 123OP3 of the bank layer 123, respectively.

A second color filter 622 and a third color filter 623 may be respectively arranged in the second opening 610OP2 and the third opening 610OP3 of the light-blocking layer 610. The second color filter 622 and the third color filter 623 may have colors respectively corresponding to light emitted by the second emission area EA2 and the third emission area EA3. In an embodiment, when green light is emitted from the second emission area EA2, the second color filter 622 is a green color filter, and when blue light is emitted from the third emission area EA3, the third color filter 623 is a blue color filter.

The overcoat layer 630 may be disposed on the light-blocking layer 610 and the color filters 620. The overcoat layer 630 is a colorless transmissive layer that does not have a color of a visible light band, and may planarize the upper surface of the light-blocking layer 610 and the upper surfaces of the color filters 620. The overcoat layer 630 may include a colorless transmissive organic material such as an acrylic resin and may be covered by the window 700.

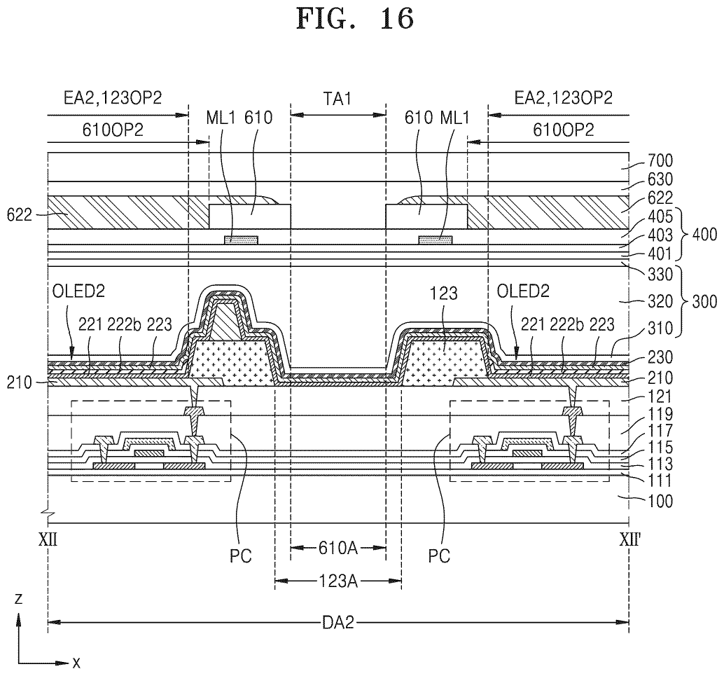

FIG. 16 is a cross-sectional view of a display panel according to an embodiment, taken along a line XII-XII′ of FIG. 10.

Referring to FIG. 16, in the second display area DA2, the first transmission area TA1 may be arranged between two emission areas in a row direction (x direction). In an embodiment, as shown in FIG. 10, the first transmission area TA1 may be arranged between the second emission areas EA2 emitting the same color of light.

The second organic light-emitting diodes OLED2 corresponding to the second emission area EA2 may be disposed on the substrate 100 to be adjacent to each other. Each second organic light-emitting diode OLED2 may be electrically connected to each pixel circuit PC described above with reference to FIG. 15, and a detailed structure of the display panel is the same as the structure described above with reference to FIG. 15, and thus differences are mainly described.

The bank layer 123 includes second openings 123OP2 defining the second emission areas EA2, but may include the bank opening portion 123A positioned between two second openings 123OP2 and corresponding to the first transmission area TA1.

The input sensing layer 400 is disposed on the encapsulation layer 300, and a portion of a conductive line forming a touch electrode of the input sensing layer 400 is arranged to surround each emission area, as described above with reference to FIG. 10. In this regard, FIG. 16 shows the first conductive line ML1 arranged to overlap a material portion of the bank layer 123 so as not to overlap the second opening 123OP2 of the bank layer 123. The first conductive line ML1 overlaps the material portion of the bank layer 123 and also overlaps the light-blocking layer 610.

The light-blocking layer 610 includes the second opening 610OP2 overlapping each second emission area EA2, but may include the first transmission opening portion 610A positioned between neighboring second openings 610OP2 and corresponding to the first transmission area TA1. The first transmission opening portion 610A may be defined by a sidewall of the light-blocking layer 610. The first transmission opening portion 610A may be at least partially filled by a portion of the overcoat layer 630.

The size (or width) of the first transmission opening portion 610A of the light-blocking layer 610 may be different from the size (or width) of the bank opening portion 123A of the bank layer 123. For example, as shown in FIG. 16, the size (or width) of the first transmission opening portion 610A of the light-blocking layer 610 may be formed to be less than the size (or width) of the bank opening portion 123A of the bank layer 123, and in this case, the size (or width) of the first transmission area TA1 may be defined by the first transmission opening portion 610A of the light-blocking layer 610, which is relatively small.

Referring to FIG. 15, a portion of the light-blocking layer 610 that covers a conductive line (e.g., the first conductive line ML1) and is positioned between neighboring emission areas overlaps two color filters having different colors. Conversely, referring to FIG. 16, a portion of the light-blocking layer 610 that covers a conductive line (e.g., the first conductive line ML1) positioned on both sides of the first transmission area TA1 with the first transmission area TA1 therebetween may be covered by no more than one of the color filters. As shown in FIG. 16, the second color filter 622 may be positioned on portions of the light-blocking layer 610 on both sides of the first transmission area TA1 with the first transmission area TA1 therebetween.

In an embodiment, at least a portion of the sidewall defining the first transmission opening portion 610A of the light-blocking layer 610 is curved. The bank opening portion 123A, defined by where an edge of the bank layer 123 meets the layer on which it is formed (the second organic insulating layer 121 in the embodiment of FIG. 16) has a polygonal shape while surrounding the first transmission opening portion 610A of the light-blocking layer 610 in plan view. This configuration prevents a phenomenon in which external light reflection is visible and secures the transmittance of light, thereby improving the quality and reliability of the display panel.

According to the embodiment described above, a display panel with improved reliability and quality and an electronic apparatus may be implemented. The scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate comprising a first display area and a second display area that is at least partially surrounded by the first display area, the first display area and the second display area having a plurality of emission areas, and the second display area having a transmission area that is positioned between neighboring emission areas of the plurality of emission areas;
a bank layer disposed on the substrate and having a first bank opening portion corresponding to the transmission area; and
a light-blocking layer disposed on the bank layer and having a transmission opening portion defined by a sidewall, the transmission opening portion corresponding to the transmission area and having a greater area than an area of the first bank opening portion,
wherein at least a portion of the sidewall defining the transmission opening portion is curved.

2. The display panel of claim 1, wherein the transmission opening portion has a circular shape.

3. The display panel of claim 1, wherein the transmission opening portion has an oval shape.

4. The display panel of claim 1, wherein the transmission opening portion comprises: a first portion having a shape of at least a portion of a circle or an oval; and a second portion having a shape of at least a portion of a circle or an oval.

5. The display panel of claim 1, wherein the transmission opening portion comprises:
a plurality of fourth portions respectively arranged at vertices of an imaginary rectangle and each having a shape of at least a portion of a circle or an oval; and
a third portion providing a wall connecting neighboring fourth portions of the fourth portions.

6. The display panel of claim 1, wherein the transmission opening portion comprises:
a plurality of sixth portions each having a shape of at least a portion of a circle or an oval; and
a fifth portion having a wall and arranged between the sixth portions.

7. The display panel of claim 1, wherein the transmission opening portion is defined by a sidewall of the light-blocking layer.

8. The display panel of claim 1, wherein an edge defining the first bank opening portion surrounds the transmission opening portion.

9. The display panel of claim 1, wherein the first bank opening portion has a polygonal shape.

10. The display panel of claim 8, wherein the first bank opening portion has a rectangular shape.

11. The display panel of claim 1, further comprising a pixel circuit layer disposed on the substrate and comprising a pixel circuit.

12. The display panel of claim 11, further comprising a light-emitting element comprising:
a first electrode disposed on the pixel circuit layer;
an emission layer on the first electrode;
and a second electrode on the emission layer.

13. The display panel of claim 12, wherein the bank layer further comprises a second bank opening portion having a sidewall on the first electrode.

14. The display panel of claim 1, wherein the light-blocking layer further comprises first, second, and third openings respectively overlapping the plurality of emission areas, and
color filters are respectively arranged in the first, second, and third openings of the light-blocking layer.

15. An electronic apparatus comprising:
a display panel comprising a first display area and a second display area that is at least partially surrounded by the first display area; and
a component disposed below the display panel and positioned in the second display area,
wherein the display panel further comprises:
a substrate comprising a plurality of emission areas arranged in the first display area and the second display area, and a transmission area arranged in the second display area and positioned between neighboring emission areas of the plurality of emission areas;
a bank layer disposed on the substrate and having a first bank opening portion corresponding to the transmission area; and
a light-blocking layer disposed on the bank layer and having a sidewall defining a transmission opening portion, the transmission opening portion corresponding to the transmission area and having a greater area than an area of the first bank opening portion,
wherein at least a portion of a sidewall defining the transmission opening portion is curved.

16. The electronic apparatus of claim 15, wherein the transmission opening portion is defined by a sidewall of the light-blocking layer.

17. The electronic apparatus of claim 15, wherein the first bank opening portion is arranged to surround the transmission opening portion.

18. The electronic apparatus of claim 15, wherein the first bank opening portion has a polygonal shape.

19. The electronic apparatus of claim 15, wherein the component comprises a sensor using light.

20. The electronic apparatus of claim 15, further comprising:
a pixel circuit layer disposed on the substrate and comprising a pixel circuit; and
a light-emitting element comprising a first electrode disposed on the pixel circuit layer, an emission layer on the first electrode, and a second electrode on the emission layer,
wherein the bank layer further comprises a second bank opening portion having an edge on the first electrode.
